(19) United States
(12) Patent Application Publication
(10) Pub. No.: US 2026/0197008 A1
(43) Pub. Date: Jul. 9, 2026

(54) CALIBRATION CIRCUIT FOR LOOP-UNROLLED SUCCESSIVE APPROXIMATION REGISTER ANALOG TO DIGITAL CONVERTERS

(71) Applicant: Kandou Labs SA, Saint-Sulpice (CH)

(72) Inventors: Arda Uran, Lausanne (CH); Armin Tajalli, Lausanne (CH)

(21) Appl. No.: 19/015,116

(22) Filed: Jan. 9, 2025

(51) Int. Cl. H03M 1/10; H03M 1/38

(52) U.S. Cl. CPC H03M 1/1009; H03M 1/38

(57) ABSTRACT

Methods and systems are described for receiving, at a loop-unrolled (LU) successive approximation register (SAR) analog to digital converter (ADC), a sequence of analog values of a PAM data signal, converting each analog value of the PAM data signal into a digital output code comprising a plurality of bits, each bit of the plurality of bits of the digital output code corresponding to a decision of a respective comparator of a plurality of comparators of the LU SAR ADC, accumulating respective statistical measurements of decisions of at least one given comparator based on the digital output codes, and updating an offset compensation of a given comparator responsive to the respective statistical measurement of decisions of the given comparator exceeding a threshold.

### CROSS-REFERENCE TO RELATED APPLICATIONS

This application claims the benefit of U.S. Provisional Patent Application 63/619,480, filed Jan. 10, 2024, naming Arda Uran, and Armin Tajalli, entitled “Calibration Circuit for Loop-Unrolled Successive Approximation Register Analog to Digital Converters” which is herein incorporated by reference in its entirety for all purposes.

### FIELD

Embodiments disclosed herein relate to communications in general and in particular to transmission of signals capable of conveying information via a communication link.

### BACKGROUND

Embodiments disclosed herein include systems and methods for data communications, including but not limited to data communications between electronic components and/or electronic devices via one or more communication links in a manner that is fast and reliable while making efficient use of resources.

One common type of communications link is a serial communications link, which may be implemented with (i) a single wire circuit relative to ground or other common reference, or (ii) multiple such circuits relative to ground or other common reference.

One type of serial communication method uses singled-ended signaling (SES). SES operates by sending a signal on one wire and measuring the signal relative to a fixed reference at the receiver. Serial communication methods may also be implemented with several wires in relation to each other. One such type of serial communication method uses differential signaling. Differential signaling operates by sending a signal on one wire and sending the opposite of that signal on a matching wire. The signal information is represented by the difference between the wires rather than their absolute values relative to ground or other fixed reference.

One type of differential signaling relevant to the systems and methods disclosed herein is Pulse Amplitude Modulation (PAM). In PAM, data is encoded in the amplitude of a series of signal pulses. In operation, amplitudes of a train of signals are varied according to the value of the data to be conveyed. PAM signals are demodulated by detecting the amplitude level of the carrier at each signaling period.

One type of PAM signaling is two-level, Non-Return-to-Zero (NRZ) PAM, sometimes referred to as PAM-2 NRZ signaling. In PAM-2 NRZ, data is encoded into two different amplitude levels, such as 0 and +1. In operation a PAM-2 receiver uses one threshold to detect received signals. Any sample above the threshold is a “+1,” and any sample below the threshold is a “0.”

Another type of PAM is three-level, NRZ PAM, sometimes referred to as PAM-3 NRZ signaling. In PAM-3 NRZ, data is encoded into three different amplitude levels, such as −1, 0, and +1. In operation, a PAM-3 receiver uses high and low reference voltage levels to detect received signals. Any sample above the high reference voltage level is a “+1,” any sample below the low reference voltage level is a “−1,” and any sample between the high and low reference voltage levels is a “0.” Signaling with three values in this manner is sometimes referred to ternary signaling with individual signals during a sample period referred to as a ternary sample. Each ternary symbol may be converted e.g., to a two-bit binary value.

There are many ways to detect information on such serial links. Previously, analog-based receivers have been sufficient in detecting PAM-2 based signaling systems for standards such as PCIe and USB. Emerging standards plan to shift from PAM-2 based signaling systems to PAM-3, PAM-4, etc. Specifically, USB4v2 plans to use PAM-3 signaling and PCIe Gen 7 plans to use PAM-4 signaling. It is expected for receivers to shift to analog-to-digital converter (ADC)-digital signal processing (DSP)-based technologies. ADC-DSP based receivers are open-loop and, support many equalization taps (feed forward equalization and decision feedback equalization), and offer large design flexibility. ADCs are employed to convert analog signals to digital signals, i.e., converting analog voltages received on wires to multiple bits of a digital signal that represent the analog voltage. Successive Approximation Register (SAR) ADCs are one type of ADC. SAR ADCs receive an analog voltage and make a sequence of comparisons of the input voltage to a series of reference voltages according to a binary search to converge on a digital output representative of the analog voltage. For an N-bit SAR ADC, N sequential comparisons are made. Loop-unrolled (LU) SAR ADCs are category of SAR ADCs that employ a multitude of comparators to reduce the latency of ADC by reducing the conversion time of the ADC.

Loop-unrolled SAR ADCs are a variation of SAR ADCs that utilize a binary search algorithm without sequential feedback loops. Instead, the entire SAR logic or multiple steps are “unrolled” and often operate in parallel or pipelined, aiming to improve speed. While they offer some advantages, they also present unique challenges in analog design. Circuit complexity is one challenge, as multiple DAC or comparator stages operate in parallel. Accuracy and matching of parallel components is another challenge. Loop-unrolled SAR ADCs utilize multiple comparators or DAC stages to operate simultaneously or in quick succession. Thus, variations in comparator offsets, capacitor matching in the DAC, and reference voltage consistency across parallel paths may lead to differential nonlinearity (DNL) errors.

Additional objects and/or advantages of the disclosed embodiments will be apparent to persons of ordinary skill in the art upon review of the Detailed Description and Figures.

### BRIEF SUMMARY

Methods and systems are described for receiving a sequence of analog values at a plurality of comparators of a loop-unrolled (LU) successive approximation register (SAR) analog to digital converter (ADC), converting each analog value of the PAM data signal into a digital output code comprising a plurality of bits, each bit of the plurality of bits of the digital output code corresponding to a decision of a respective comparator, and accumulating respective statistical measurements of decisions of at least one comparator based on the digital output codes and, and updating an offset compensation of a given comparator responsive to the respective statistical measurement of decisions of the given comparator deviating from a predetermined desired measurement by a threshold amount.

### BRIEF DESCRIPTION OF THE DRAWINGS

Various embodiments in accordance with aspects of the present disclosure will be

described with reference to the drawings, in which:

FIG. 1 is a block diagram of a communications system, in accordance with some embodiments.

FIG. 2 is a block diagram of a data lane that includes an ADC-DSP based receiver, in accordance with some embodiments.

FIG. 3 is a block diagram of a successive approximation register (SAR) based ADC.

FIG. 4 is a block diagram of a loop-unrolled (LU) SAR-ADC.

FIGS. 5A and 5B are diagrams illustrating the effects of comparator offset in a LU SAR-ADC.

FIG. 6 is a diagram illustrating effects of comparator offset on effective number of bit (ENOB) loss for various bit positions.

FIGS. 7A-7E illustrate the sensitivity of bit probabilities to 5 least significant bits (LSBs) of offset added to a LU SAR ADC having seven comparators in various noise scenarios.

FIGS. 8A-8E illustrates sensitive of bit probabilities to comparator offset in the presence of inter-symbol interference (ISI) in various noise scenarios.

FIG. 9 is a block diagram of a comparator offset calibration circuit, in accordance with some embodiments.

FIG. 10 illustrates a comparator offset calibration sequence for a system having 10 LSB of noise, in accordance with some embodiments.

FIG. 11 illustrates a comparator offset calibration sequence for a system having 2 LSB of noise, in accordance with some embodiments.

FIG. 12 illustrates a comparator offset calibration sequence for a system having 0 LSB of noise, in accordance with some embodiments.

FIG. 13 is a block diagram of a LU SAR ADC having a barrel shifter for added calibration precision, in accordance with some embodiments.

FIG. 14 illustrates a comparator offset calibration sequence for a barrel-shifted system having 10 LSB of noise, in accordance with some embodiments.

FIG. 15 illustrates a comparator offset calibration sequence for a barrel-shifted system having 2 LSB of noise, in accordance with some embodiments.

FIG. 16 illustrates a comparator offset calibration sequence for a barrel-shifted system having 0 LSB of noise, in accordance with some embodiments.

FIG. 17 is a flowchart of a method, in accordance with some embodiments.

### DETAILED DESCRIPTION

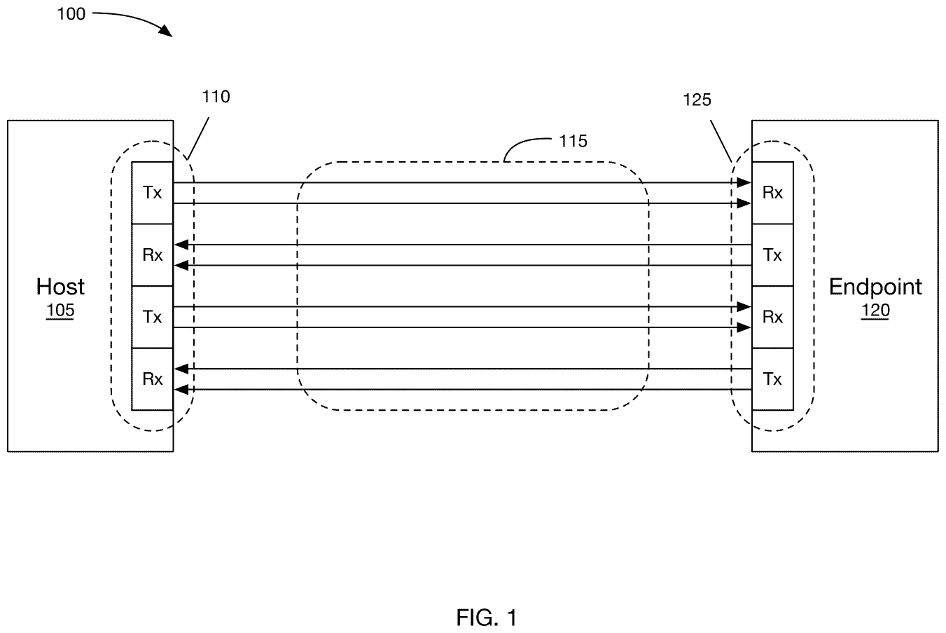

FIG. 1 is a block diagram of a communications system 100. As shown, communications

system 100 includes a host 105 connected to an endpoint via a multi-wire communications channel 115. As shown, host 105 and endpoint 120 each include transceivers 110 and 125, respectively. The multi-wire communications channel 115 includes two bidirectional data lanes. In some embodiments, the bidirectional data lanes are serial data lanes associated with e.g., a Universal Serial Bus (USB) link, a peripheral component interface express (PCIe) link, or other protocols that utilize serial transmission of data. The host 105 may be e.g., a central processing unit (CPU) on a motherboard. The endpoint 120 may be a memory device, a network interface controller (NIC), an artificial intelligence (AI) engine, a graphics processing unit (GPU), a data processing unit (DPU), encryption device, or other hardware for communicating with host 105 via a serial communication network. The multi-wire communications channel 115 may correspond to traces on a printed circuit board (PCB). Alternatively, multi-wire communications channel 115 may be a cable comprising twisted pairs.

Increasing the throughput of a communications protocol may be performed via several methods, including but not limited to (i) increasing the data symbol rate, (ii) increasing the number of data lanes in the communications channel, and (iii) increasing the number of available signaling levels transmitted on the bus, often referred to as Pulse Amplitude Modulation (PAM-X) signaling. As previously described, USB 4v2 and PCIe Generation 7 are adapting to larger throughput demands by shifting to PAM-3 and PAM-4 signaling, respectively. In such environments, ADC-DSP-based receivers are desirable.

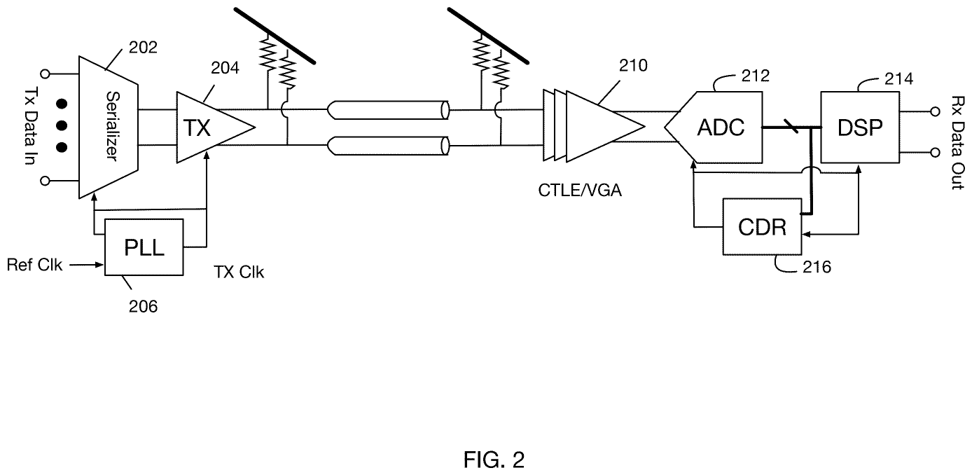

FIG. 2 is a block diagram of a data lane, e.g., one of the links of FIG. 1. As shown, the data lane includes an ADC-DSP-based receiver. The data lane shown in FIG. 2 may be part of a PCIe data link, a USB link, or other various signaling protocols. As shown, the data lane includes a transmitter at a first end of the channel having a serializer 202 configured to receive parallel data and to output serialized data to a transmit driver 204. The transmitter further includes a phase-locked loop (PLL) 206 configured to generate a transmit clock from a reference clock. A receiver is connected at the other end of the channel, and includes a continuous time linear equalizer (CTLE) and variable gain amplifier (VGA) stage 210 configured to equalize and amplify an input signal and to provide the equalized/amplified input signal as an analog input signal to ADC 212. The ADC 212 is configured to convert the analog input signal to a digital output signal. The receiver further includes a digital signal processor (DSP) 214 configured to apply e.g., feed forward equalization (FFE) and decision feedback equalization (DFE) via numerous delay taps, multipliers, and adders. ADC-DSP based receivers benefit from the ADC being open loop, having digital pipelining, many equalization taps, and other design flexibility, at the cost of consuming more power than analog-based receivers.

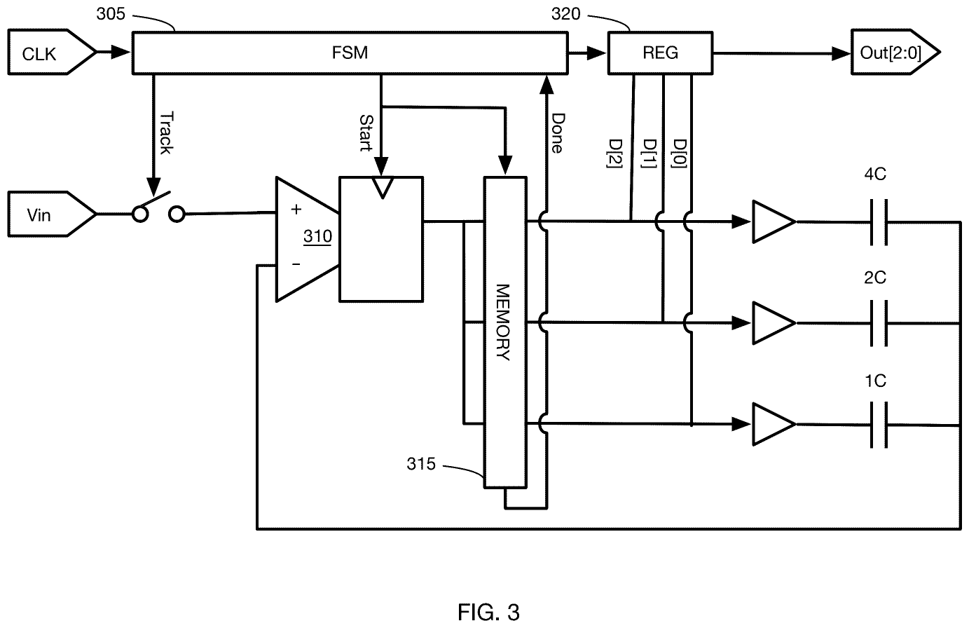

ADC 212 in FIG. 2 may take the form of a successive Approximation Register (SAR) ADC. FIG. 3 is a block diagram of a SAR-ADC. As shown, the SAR-ADC includes a finite state machine (FSM) 305, a comparator 310, memory 315, and a register 320. The FSM 305 initiates a conversion by sampling and holding the input signal Vin via the ‘Track’ signal. The differential voltage is provided to comparator 310, which begins making successive comparisons of the input signal to a varying reference voltage. FSM 305 provides a ‘Start’ signal comparator 310 to compare the input voltage to a value of half the maximum voltage VDD, ½VDD. The capacitor(s) associated with the MSB (4C) are manipulated, and, depending on the MSB decision, the next comparison against either 1/4 VDD or 3/4 VDD is made until all comparisons have been made. The memory 315 outputs a ‘Done’ signal to FSM 305, and the decisions D[2: 0] generated from each comparison are loaded into the register 320. For a SAR ADC having N bits of resolution, N comparisons are made. Thus, the higher the resolution of a SAR ADC, more comparisons are needed which leads to increased latency.

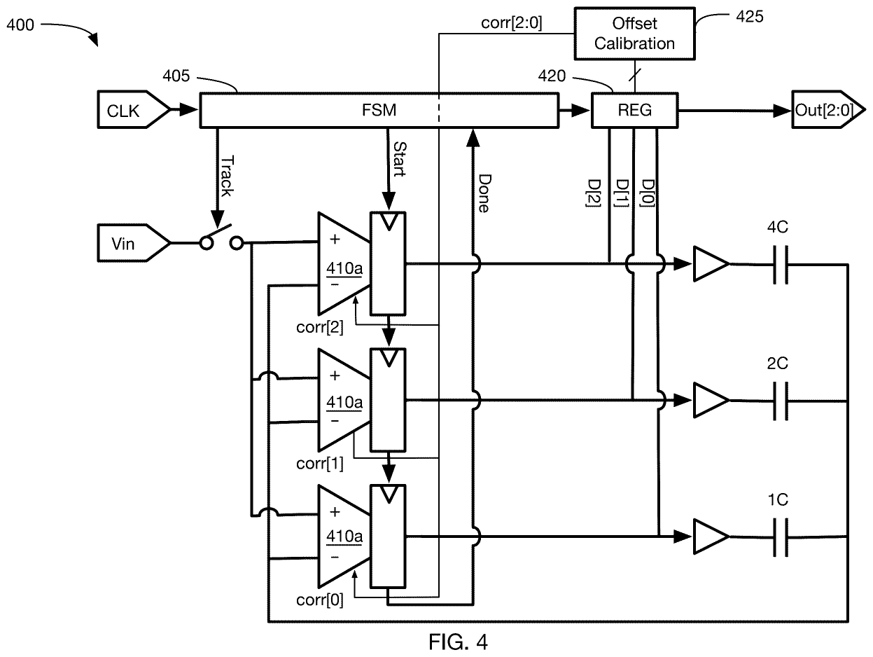

In the conventional SAR-ADC which includes one comparator, the comparator is reset after each comparison, which increases overall latency of the ADC. Further, a memory is included to store the decisions. FIG. 4 is a block diagram of a loop-unrolled (LU) SAR-ADC. As shown, the LU SAR-ADC includes a plurality of comparators configured to make the successive comparisons. The use of multiple comparators reduces the latency of the ADC. Further, the decisions are stored at the comparator output rather than a dedicated memory device. The LU SAR-ADC operates similar to the conventional SAR-ADC, with the exception being that the multiple comparators are triggered in a cascading fashion to perform the successive comparisons rather than setting and resetting a single comparator. In a single comparator SAR ADC, however, any inherent offset in the comparator directly corresponds to the offset of the ADC. In the LU SAR-ADC, comparator offsets in the multiple comparators may lead to severe performance degradation. Further, the calibration mechanism is more challenging than the single comparator SAR-ADC. Some previous analog methods of calibrations involve shorting the inputs to each comparator, while offset is injected until the comparators reach a metastable state. Such calibration methods require dedicated offset calibration periods between conversions, increasing the latency of the LU SAR-ADC and thereby diminishing the effects of the loop-unrolling. Thus, embodiments are described herein for a digital calibration technique of a LU SAR-ADC to reach sampling rates in PCIe Generation 6, Compute Express Link (CXL) 3.0 and beyond.

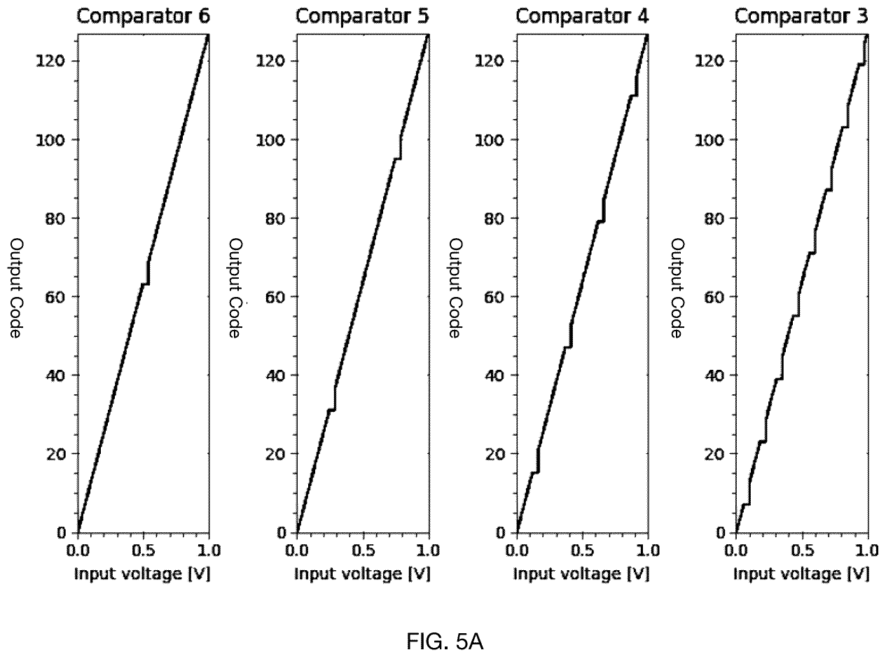

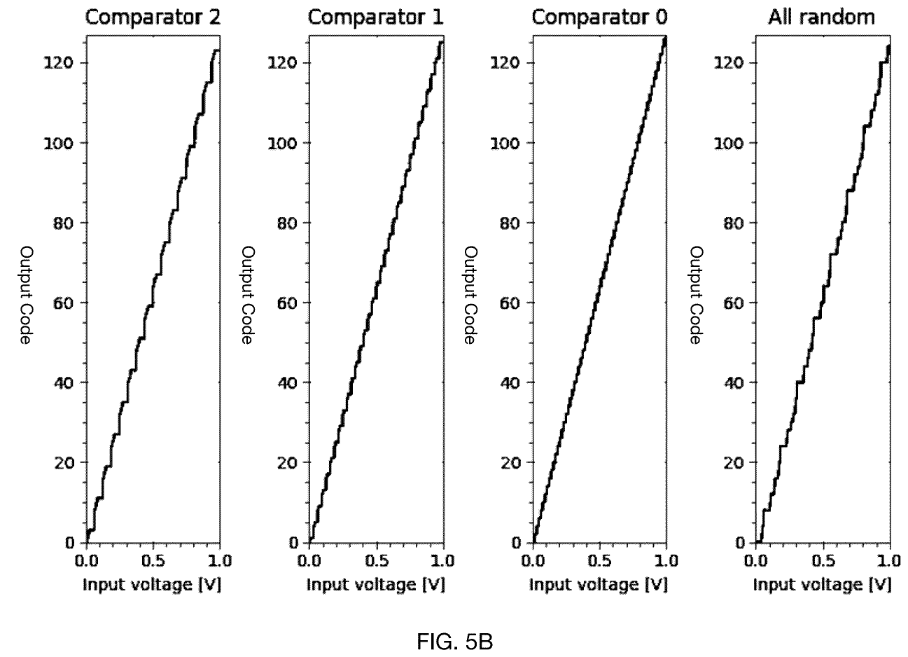

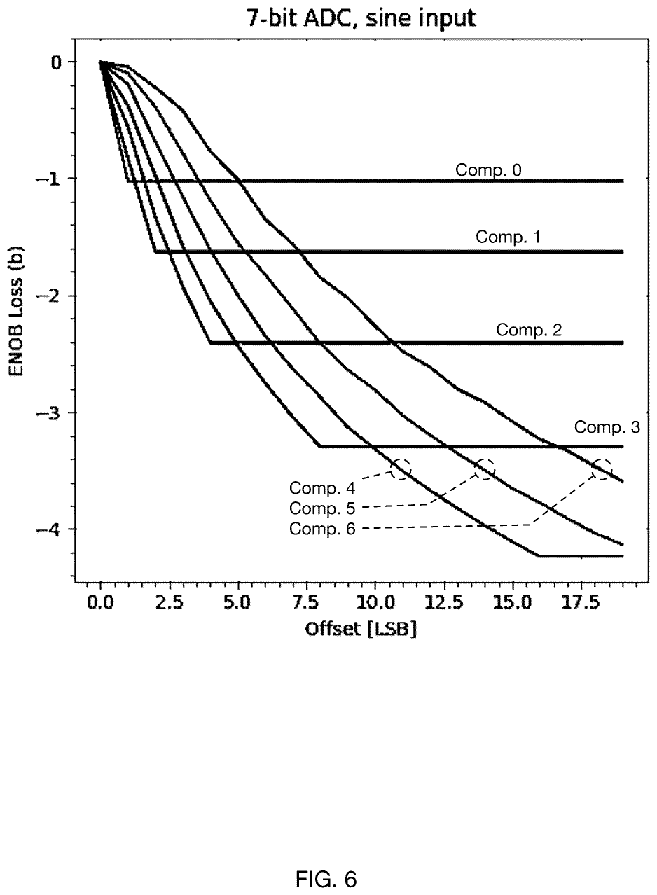

FIGS. 5A and 5B illustrate the effect of comparator offset on the transfer function of a 7-bit LU SAR-ADC. In FIGS. 5A and 5B, comparator 6 represents the MSB of the ADC and comparator 0 is the LSB of the ADC. As shown, each plot illustrates the transfer function when the indicated comparator has an offset of 5 LSBs. The last plot illustrates the transfer function when all comparators have a randomized offset between −5 and +5 LSBs. Offset in each comparator effectively creates missing digital output codes (i.e., dead zones) in the ADC transfer function. The effect of random comparator offset in all the comparators is comparable to noise at the ADC output. FIG. 6 illustrates the effect of offset on the expected number of bits (ENOB) of the ADC. As shown, comparators in the LSB react quickly to offset, however the effects are bounded. In the MSBs comparators, the effects occur slowly but are potentially more detrimental depending on the amount of offset added.

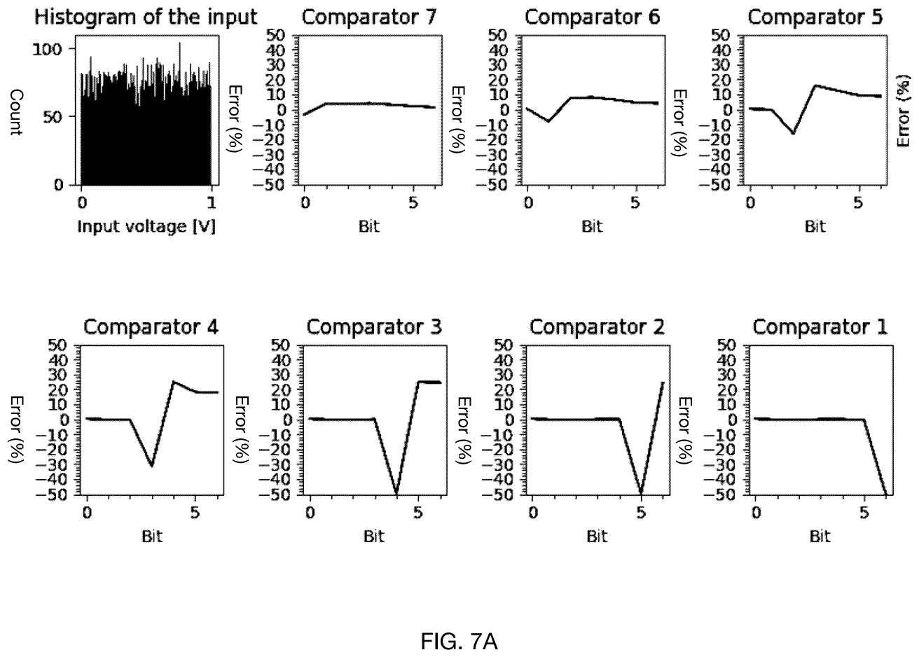

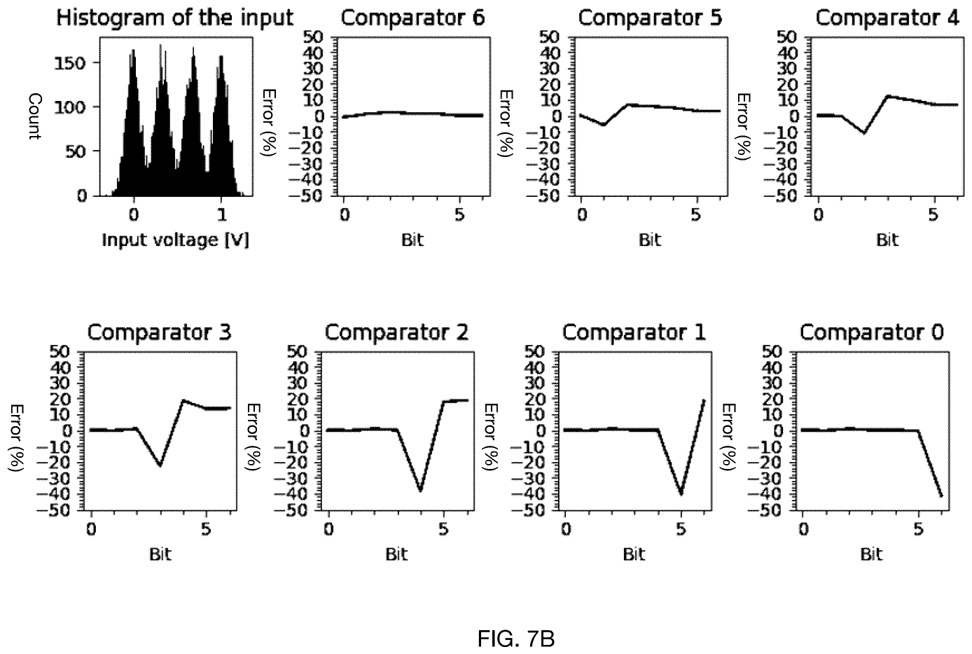

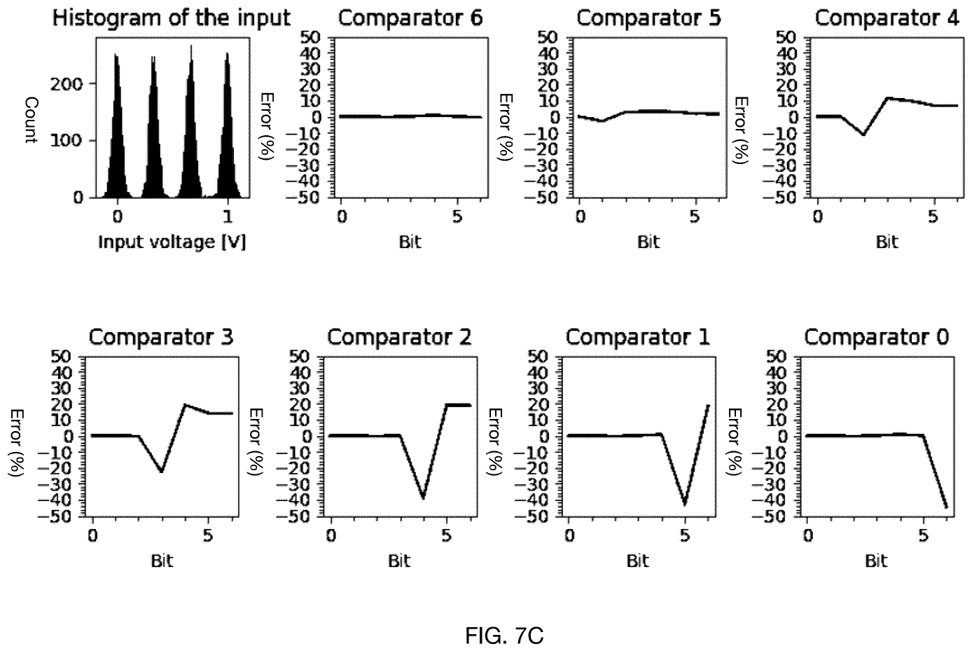

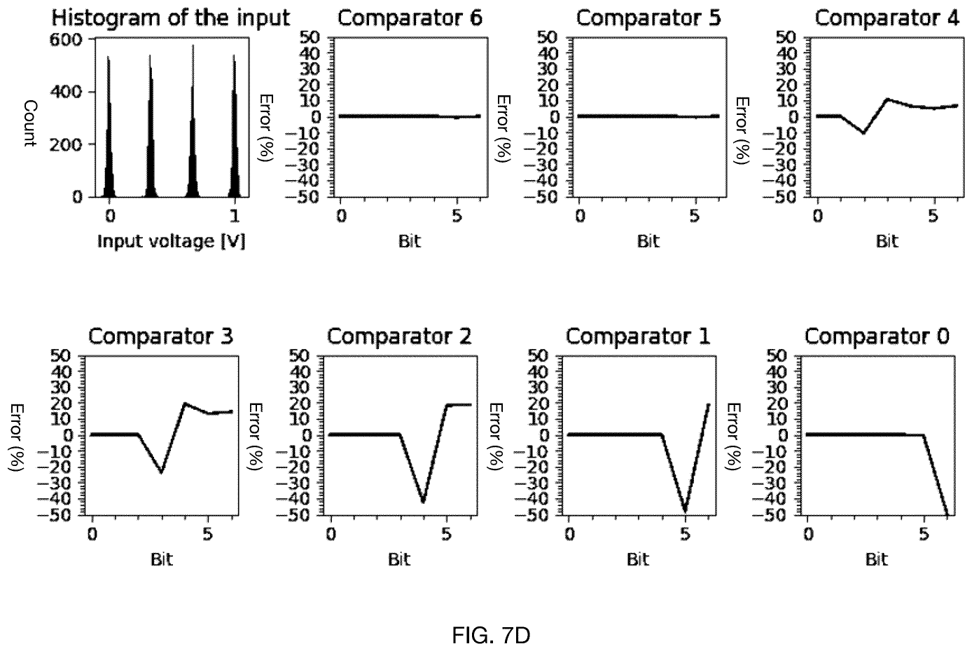

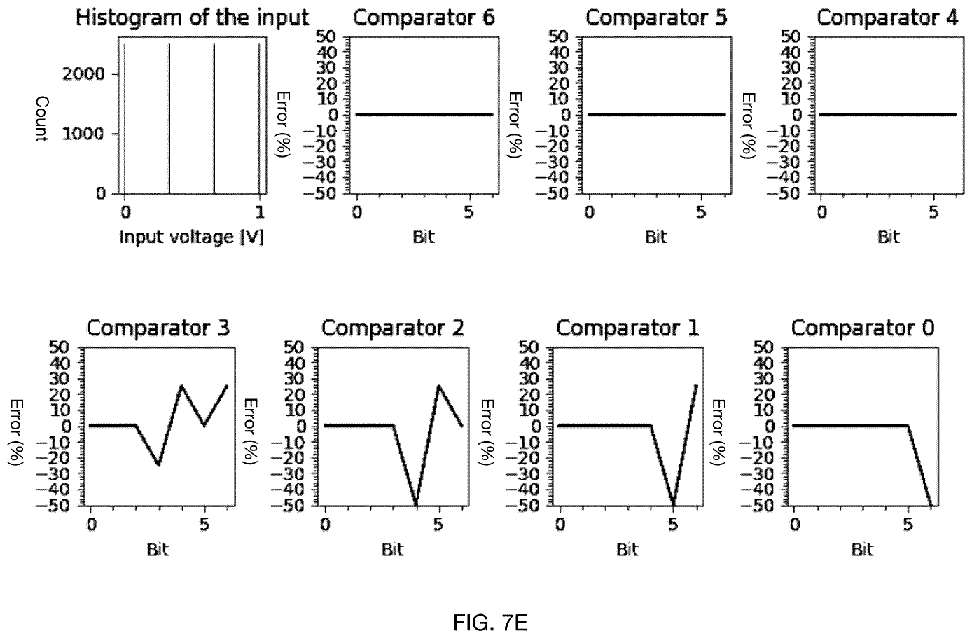

FIGS. 7A-7E illustrate the effect of comparator on bit probabilities in various noise scenarios. In random data, it is expected that each position of the digital output code is approximately 50-50 over time. In FIGS. 7A-7E, comparator offset causes the probabilities of each comparator to deviate from 50-50. In the results of the experiment illustrated by FIGS. 7A-7E, 5 LSBs of offset are added to one of the comparators, and 10k analog voltages are converted to digital output codes. The error for each bit is the deviation from a 50-50 probability. Some notable observations may be made. First, the comparators in the LSB positions are more sensitive to comparator offsets than comparators in the MSB positions. This is illustrated by the graphs in the column for comparator 0, which illustrate that the probability deviates completely from 50-50, i.e., there is so much comparator offset that the comparator no longer toggles. Another observation made is that offset on the MSBs is not detectable from deviations in the probability if the amount of noise is low. Looking at the column of comparator 6, this is illustrated by the noticeable deviation from 50-50 in the random input with uniform distribution. The deviation is also present in the PAM-4 input having a high amount of noise (sigma=10 LSB). However, in the PAM-4 inputs having low noise (Sigma=5, 2, and 0 LSB), there is no deviation from 50-50. This is because comparator 6 is the first comparison and is slicing the input signal against ~500 mV. In the 5, 2, and 0 LSB noise scenarios, the input signal is never at 500 mV. In the 10 LSB and random input scenarios, however, the input signal does occasionally have a value of 500 mv. A similar observation may be made for comparator 5 in the 2, 0 LSB of noise scenarios and comparator 4 in the 0 noise scenario.

Another observation made is that the offset on a comparator affects the probability of the next bits. Looking at comparator 6 in the random input scenario, the offset causes the probability of comparator 5 to slightly increase. This is due to comparator 6 making a wrong decision at an input of around ~500 mV, and any wrong decisions cause comparator 5 to make a similar wrong decision. This effect is more noticeable on comparators on the LSB position, as the decisions made with 5 LSB will more frequently cause erroneous decisions in the next LSB comparator. In comparator 1, 5 LSB of offset causes both comparators 1 and 0 to no longer toggle, thus effectively losing 2 bits of resolution in the ADC.

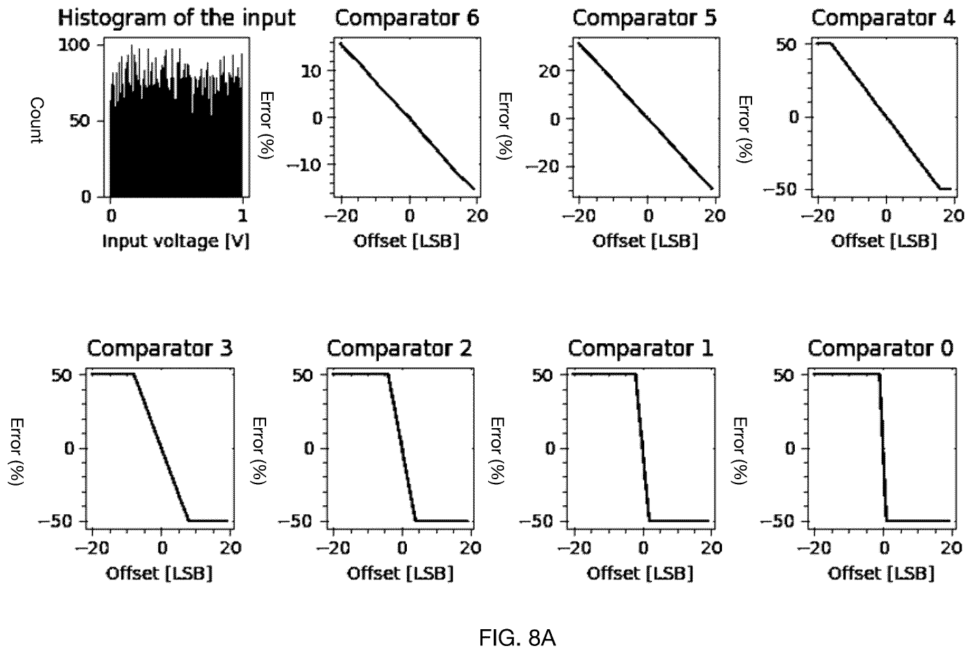

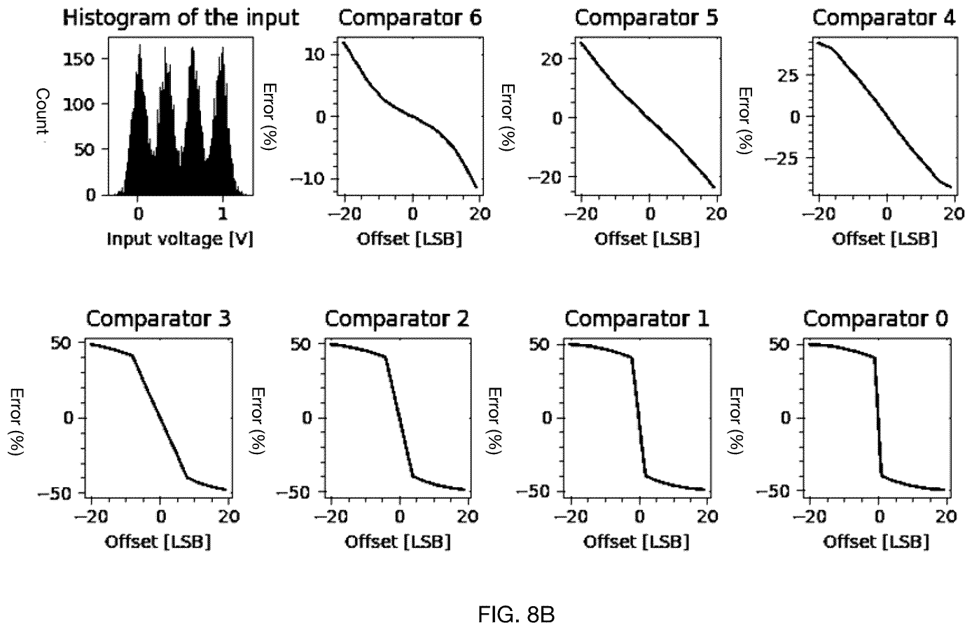

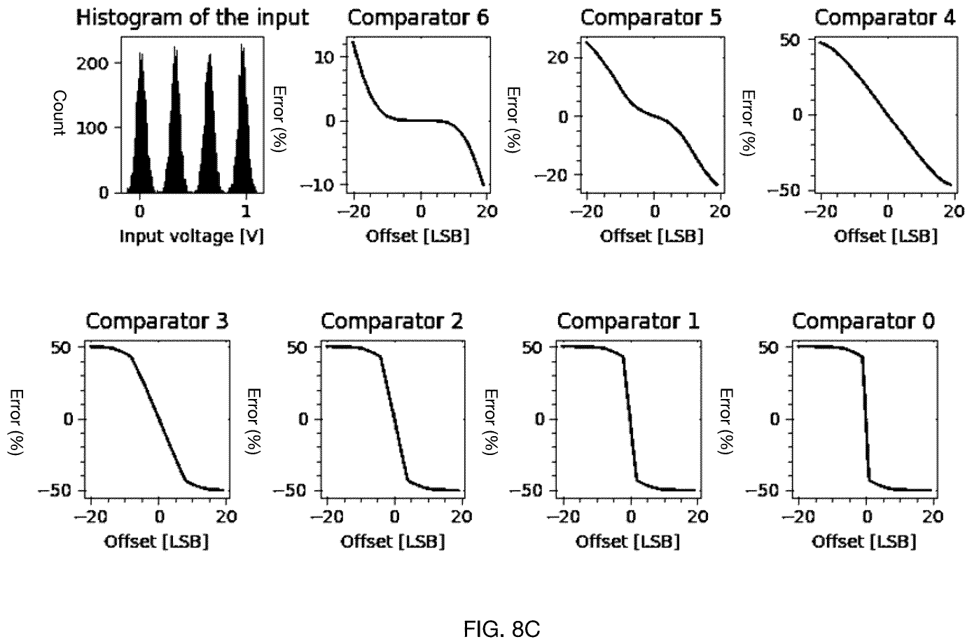

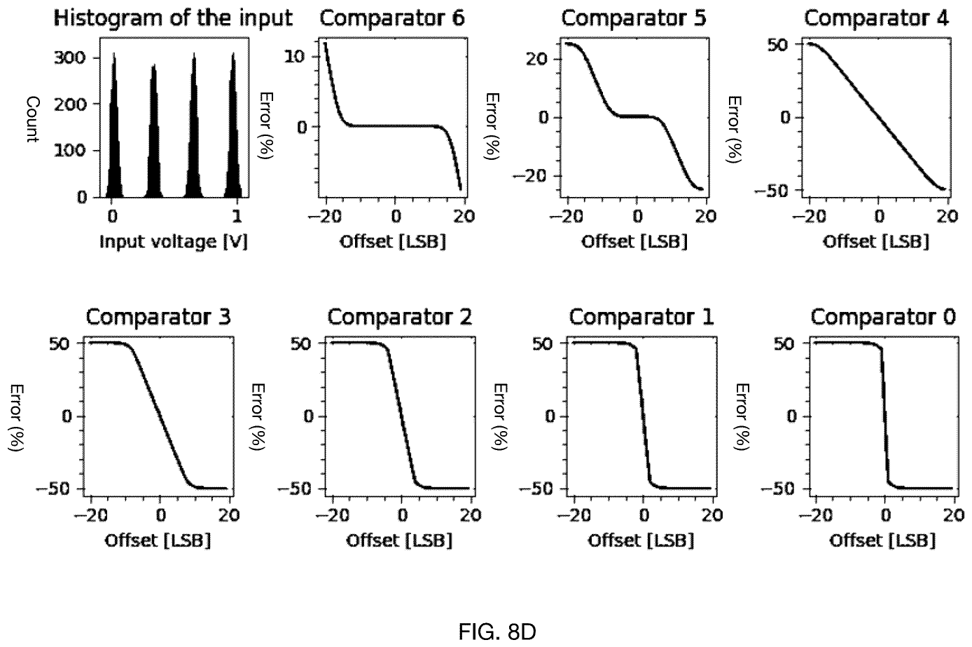

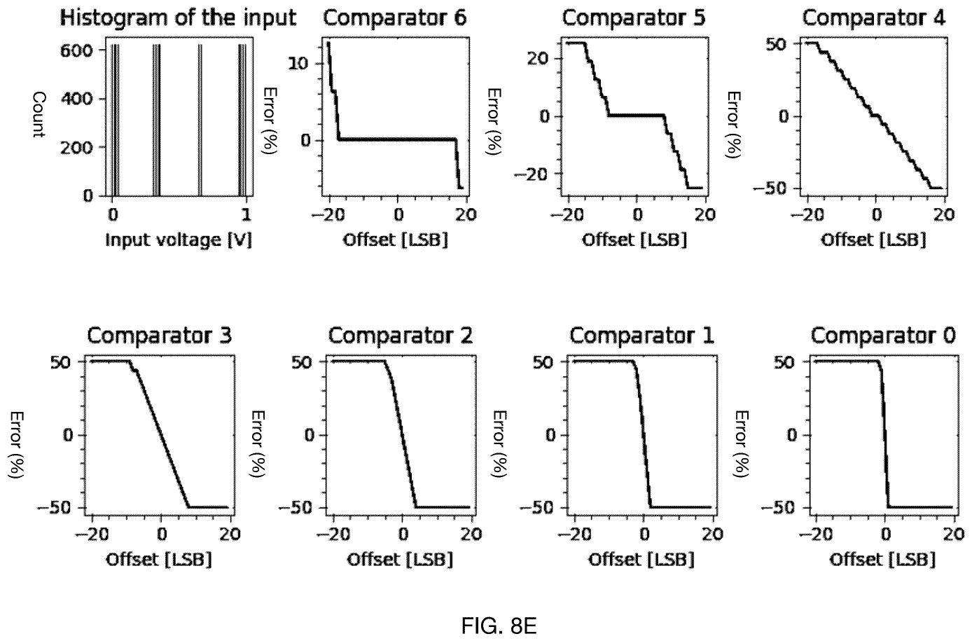

FIGS. 8A-8E include a multitude of waveforms that illustrate the sensitivity of bit probabilities to offset in the presence of inter-symbol interference (ISI). In the results of the experiment illustrated in FIGS. 8A-8E, for a 8 bit ADC, the offset for each comparator is swept −20 LSB to +20 LSB, and the corresponding bit deviation from 50% probability is plotted. As shown, the presence of ISI helps middle bit positions of the ADC in low-noise cases (e.g., comparators 4, 3, and 2), however the MSB dead zones remain.

### LU SAR ADC Calibration

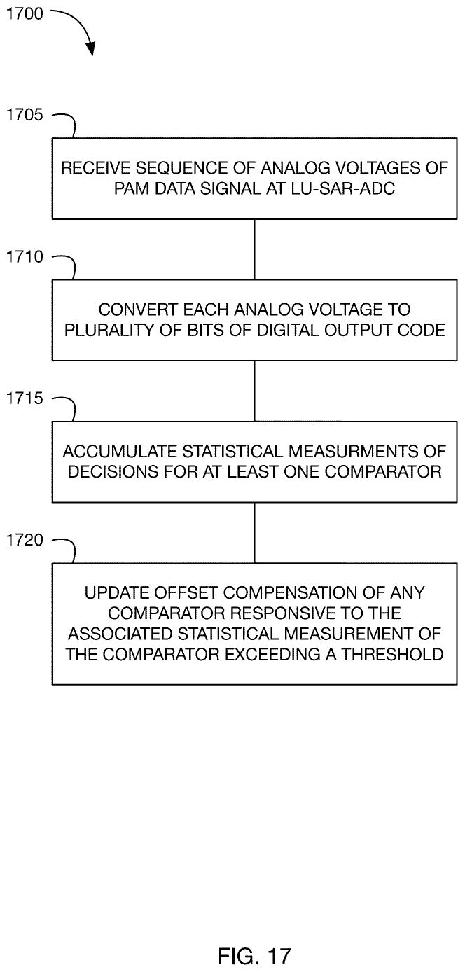

Based on the above, comparator offset in a LU SAR-ADC may lower the resolution of the ADC, and thus calibration of the comparators is desired. Methods and systems are described below for a comparator offset calibration scheme for LU SAR-ADCs. FIG. 17 is flowchart of a method 1700 in accordance with some embodiments. As shown, method 1700 includes receiving 1705, at a LU SAR-ADC, a sequence of analog values of a PAM data signal. The method further includes converting 1710 each analog value of the PAM data signal into a digital output code comprising a plurality of bits, each bit of the plurality of bits of the digital output code corresponding to a decision of a respective comparator of a plurality of comparators of the LU SAR ADC. The method further includes accumulating 1715 respective statistical measurements of decisions of at least one given comparator based on the digital output codes, and updating 1720 an offset compensation of a given comparator responsive to the respective statistical measurement of decisions of the given comparator exceeding a threshold.

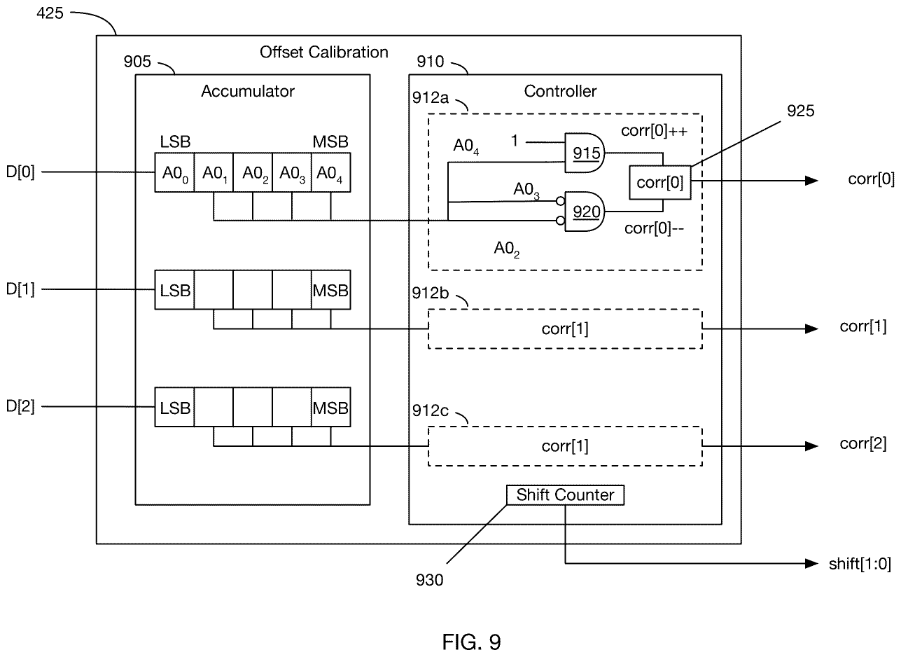

FIG. 9 is a block diagram of a comparator offset calibration circuit 425, in accordance with some embodiments. As shown, the comparator offset calibration circuit 425 includes an accumulator 905 and a controller 910. Offset calibration circuit 425 may include additional components not shown, and the accumulator 905 and controller 910 may be implemented in many ways. As shown, the accumulator 905 is configured to receive data decisions from each comparator of a 3-bit LU SAR ADC. The accumulator includes multiple registers to accumulate the ratio of positive to negative decisions generated by each comparator. The registers may be incremented every time a positive decision is made and decremented every time a negative decision is made, or vice versa. The decisions are accumulated via a LSB position of the register.

The comparator offset calibration circuit 425 further includes a controller 910. The controller 910 is configured to monitor the bit probabilities of each register and to increase or decrease the comparator offset in the event a bit probability of a given comparator exceeds a threshold. For example, if a threshold of 50-50 is desired, then the controller 910 may adjust the comparator offset if the bit probability for any comparator exceeds 55-45 in either direction. Controller 910 is shown as including logic circuits 912a/912b/912c configured to perform such a monitoring function. An example schematic for the logic circuit 912a monitoring D[0] bit probabilities is shown. As shown, the logic circuit 912a includes an AND gate 915 configured to monitor the MSB of the register, ‘A0₄’. If A0₄ flips to a 1, this may indicate that too many positive decisions have accumulated with respect to negative decisions. Thus, the offset of the comparator may be too low, and the correction value corr[0], shown as beings stored in a register 925, may be incremented. The logic 912a further includes a second AND gate 920 having inverting inputs configured to receive positions A0₃ and A0₂. If both values are low, this may indicate that too many negative decisions are accumulated with respect to the number of positive decisions accumulated, indicating that the offset correction value corr[0] is set too high. Thus, the offset correction value corr[0] may be decremented. Similar logic circuits may be implemented for 912b and 912c. The logic circuit 912a is one conceptual way to implement the bit probability monitoring function, and it should be noted that various other implementations may be suitable. For example, the controller 910 may include software monitoring the status of the registers and modifying offset correction values corr[2:0] when any corresponding bit probability exceeds the threshold. In some embodiments, the controller may analyze the bit probabilities of all the comparators as a whole and make weighted adjustments to the offset correction signals for each comparator. For example, looking back at FIG. 7A, in the uniform distribution input, the bit probabilities due to offset of a given comparator may impart a shift in the bit probabilities in the adjacent comparator. For a 5 LSB offset in comparator 5, which results in approximately a 40-60 bit probability, there is an opposite 60-40 bit probability in comparators 4 and 3 despite there being no offset applied to theses comparators in the experiment. Similarly, in the scenario in which 5 LSB offset is applied to comparator 4, resulting in approximately a 30-70 bit probability, there is an opposite 70-30 bit probability seen in comparator 3, and other similarly high bit probabilities in comparators 2-0. Thus, depending on the aggregated statistical measurements of decisions for all comparators in the ADC, the controller may adjust MSBs with more weight, thus taking into account the notion that the adjustments to the MSBs will affect the bit probabilities of the LSBs.

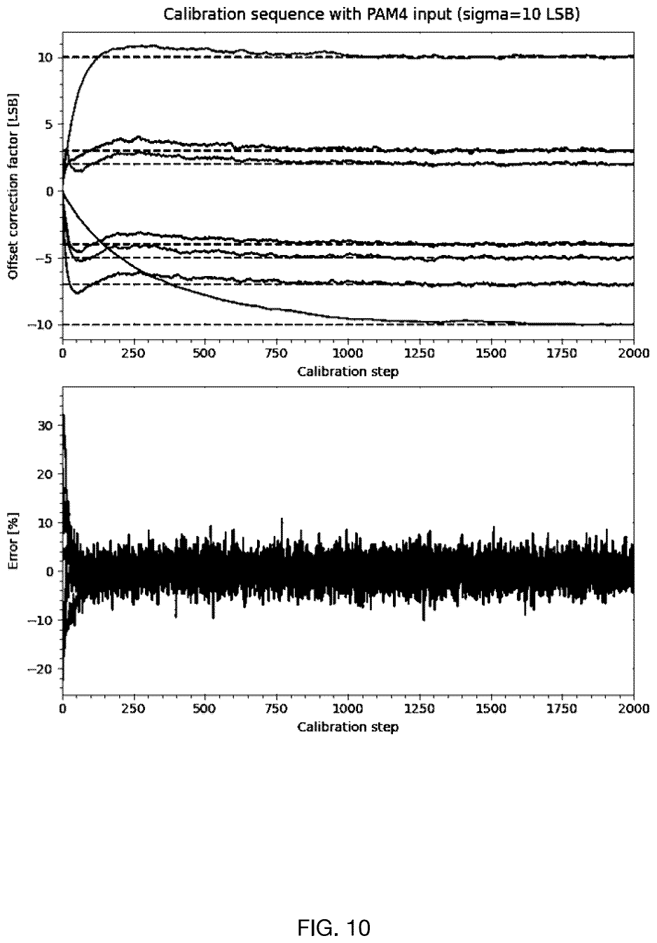

FIG. 10 illustrates the comparator offset calibration procedure over time in a high noise (10 LSB) PAM4 input signal environment. The graph on the bottom illustrates the error deviation from 50-50 for each comparator. The graph on the top illustrates corrections made to the comparator offset compensation for each comparator. The horizontal dotted lines illustrate the actual comparator offset for each comparator. The solid lines illustrate the value of the correction signal applied to the comparator over time. As shown, the correction signal for every comparator converges on the actual offset for each comparator.

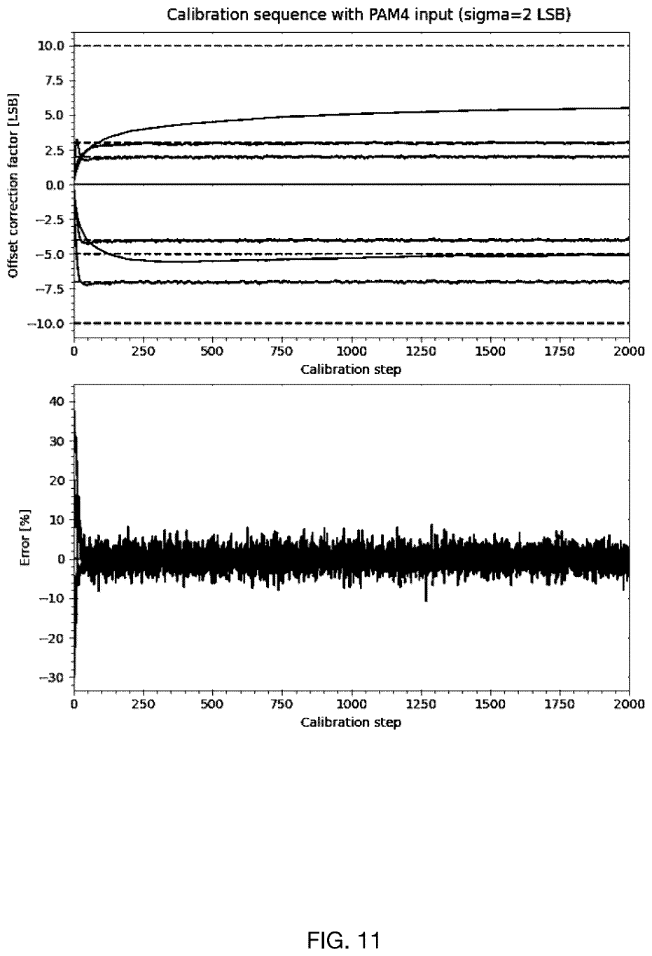

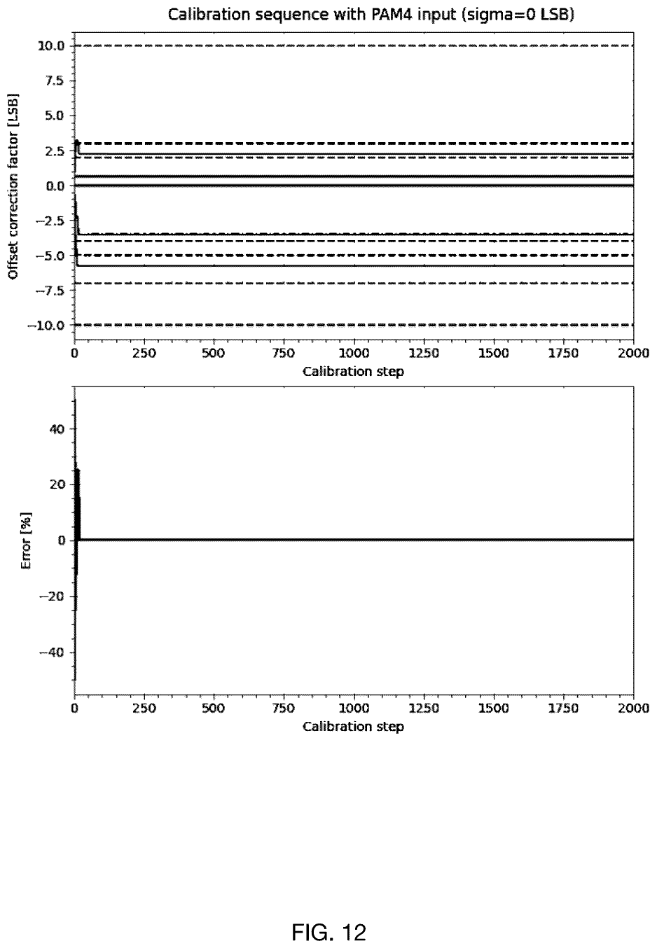

FIG. 11 illustrates a similar diagram of FIG. 10, however the noise is set to 2 LSB. In FIG. 11, the comparator offset calibration procedure properly calibrates 6 out of the 7 comparators. Comparator 5, which has 10 LSB of offset, is only partially corrected. FIG. 12 illustrates an even lower noise scenario. In some embodiments, as described above, the MSB comparators may read 50-50 bit probabilities even in the presence of comparator offset. In such scenarios, the offset may not impact the reliability and accuracy of the ADC. Some applications, such as physical layer serializer/deserializers (SERDES) used in e.g., PCIe links, experience bit error rates on the order of 1E-6. In such scenarios, the offset correction may not be needed in the MSB comparators, and only the comparators in the LSB positions are corrected to maintain accuracy and the expected number of bits of resolution.

In some embodiments, an apparatus includes a LU SAR-ADC, the LU-SAR ADC comprising a plurality of comparators connected in series, the plurality of comparators configured to receive a sequence of analog values of a PAM data signal and to convert each analog value of the PAM data signal into a digital output code comprising a plurality of bits, each bit of the plurality of bits of the digital output code corresponding to a decision of a respective comparator. The apparatus further includes an offset calibration circuit configured to accumulate respective statistical measurements of decisions of at least one comparator based on the digital output codes and to update an offset compensation of a given comparator responsive to the respective statistical measurement of decisions of the given comparator exceeding a threshold.

In some embodiments, the offset calibration circuit is configured to accumulate the respective statistical measurement of decisions in corresponding registers, and responsive to the statistical measurement of decisions of a given comparator exceeding the threshold, provide a comparator offset correction value to the given comparator. In some embodiments, the comparator offset correction value is incremented or decremented by a fixed step value. In alternative embodiments, the offset correction value is dependent on a bit position of the plurality of bits of the digital output code associated with the given comparator. In a further embodiment, the offset correction values for a plurality of comparators may be updated. In such an embodiment, the offset calibration circuit may include a controller configured to analyze the statistical measurements of decisions for each comparator, and update each comparator offset correction value based on the aggregation of the statistical measurements of decisions.

### Barrel Shifting to Reduce Calibration Latency

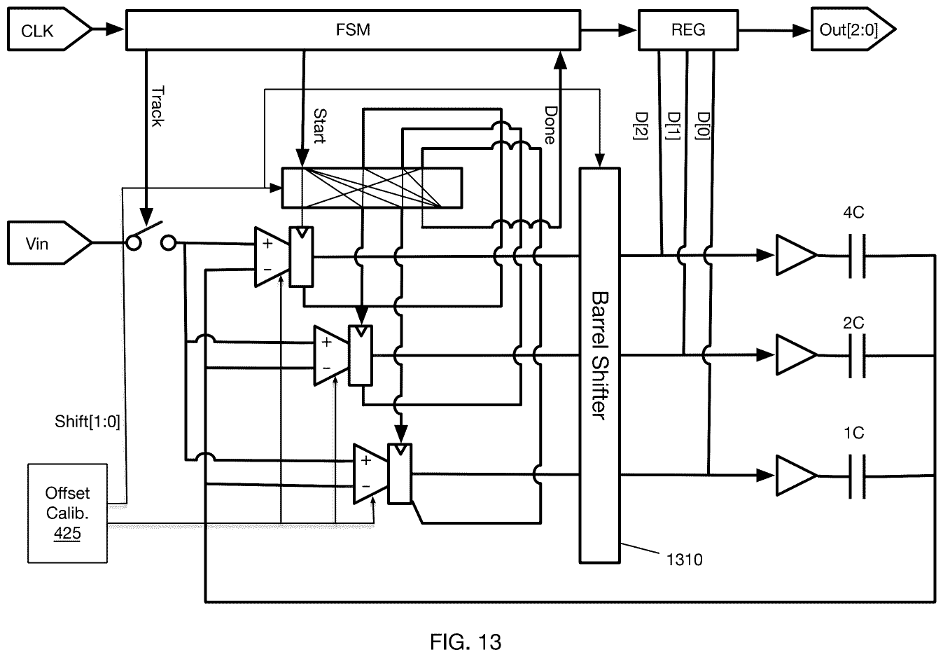

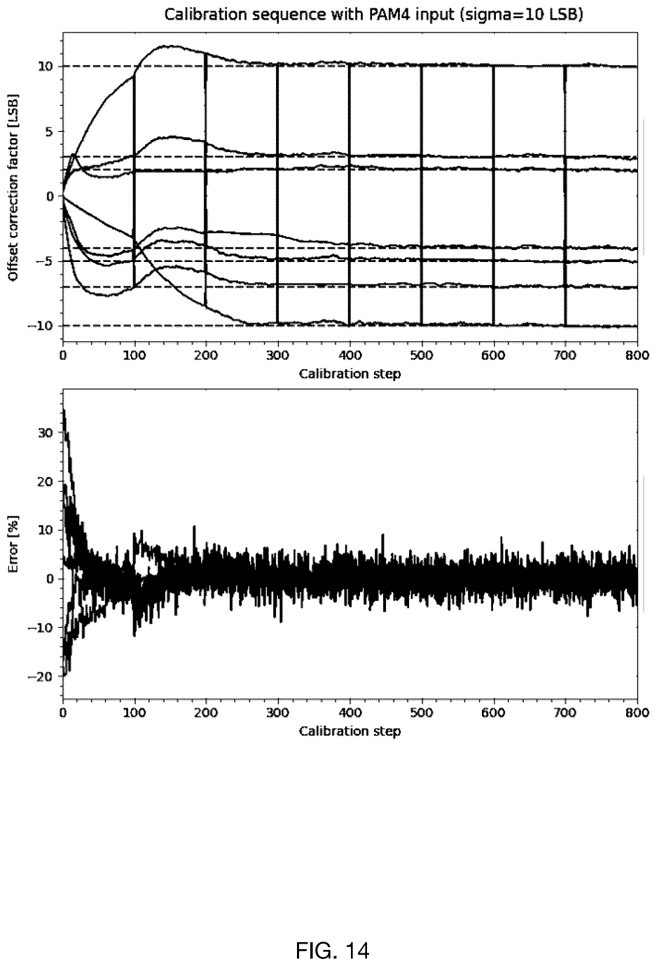

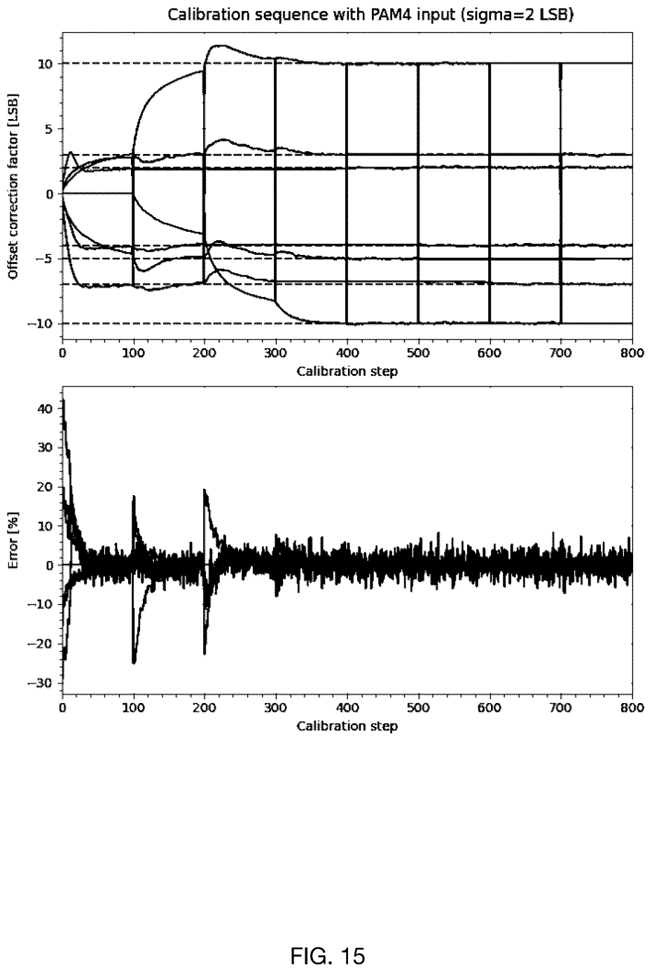

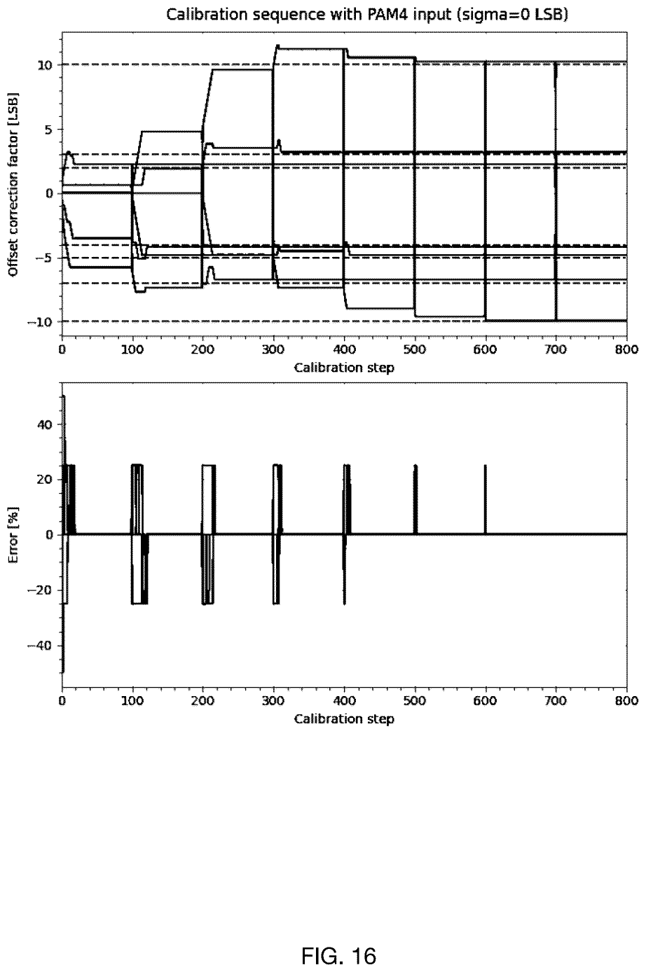

In some applications, especially those requiring a very low error rate at the output of the ADC (such as on the order of 1E-12 or lower), it may be desired that the offset is corrected in every comparator including those in the MSB positions. As is apparent in the graphs of FIGS. 11 and 12, the comparators in the MSB positions may also be calibrated, although the time to compensate for offset increases as the offset calibration needs to gather more samples. On the contrary, the offset corrections ocor[0] and ocor[1] are calibrated quickly for the LSB comparators. Thus, some embodiments may take advantage of the speed in which the offset in comparators in the LSB positions are corrected by implementing a barrel shifter configured to cycle the bit positions of the comparators of the LU SAR-ADC. In such embodiments, every comparator is cycled through the LSB positions of the digital output code and thus the offset of every comparator may be compensated accurately and more quickly. In some embodiments, the apparatus 400 further includes a barrel shifter configured to periodically rotate the plurality of comparators through bit positions of the plurality of bits of the digital output code. FIG. 13 illustrates such an embodiment incorporating a barrel shifter 1310. The other aspects of FIG. 13 may be similar to those described with respect to FIG. 4. As shown, the comparator offset calibration circuit 425 is further configured to output a barrel shift signal Shift[1:0]. The shift signal Shift[1:0] may be configured to select which DAC code output bit position each comparator generates. Such switching further involves switching which comparator receives the Start signal from the FSM, the order of the comparisons via the cascaded clock signals, and which comparator outputs the Done signal back to the FSM indicating the conversion is complete. In some embodiments, each comparator is configured to receive a respective phase of a conversion clock signal, and the barrel shifter is configured to select the respective phase of the conversion clock signal for each comparator. The LU SAR-ADC may include a capacitor network configured to store the analog value on a differential pair of nodes for each conversion, and wherein each capacitor in the capacitor network is configured to receive a decision from a respective comparator manipulate the analog voltage based on the decision. The barrel shifter may be configured to select, for each capacitor in the array, the decision received by the capacitor.

It should be noted that the term “circuit” may mean, among other things, a single component or a multiplicity of components, which are active and/or passive, and which are coupled together to provide or perform a desired function. The term “circuitry” may mean, among other things, a circuit, a group of such circuits, one or more processors, one or more state machines, one or more processors implementing software, one or more gate arrays, programmable gate arrays and/or field programmable gate arrays, or a combination of one or more circuits (whether integrated or otherwise), one or more state machines, one or more processors, one or more processors implementing software, one or more gate arrays, programmable gate arrays and/or field programmable gate arrays.

It should be further noted that the various circuits and circuitry disclosed herein may be described using computer aided design tools and expressed (or represented), as data and/or instructions embodied in various computer-readable media, for example, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and HLDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such formatted data and/or instructions by carrier waves include, but are not limited to, transfers (uploads, downloads, e-mail, etc.) over the Internet and/or other computer networks via one or more data transfer protocols (e.g., HTTP, FTP, SMTP, etc.). The embodiments described are also directed to such representation of the circuitry described herein, and/or techniques implemented thereby, and, as such, are intended to fall within the scope of the present embodiments.

Moreover, the various circuits and circuitry, as well as techniques, disclosed herein may be represented via simulations and simulation instruction-based expressions using computer aided design, simulation and/or testing tools. The simulation of the circuitry described herein, and/or techniques implemented thereby, may be implemented by a computer system wherein characteristics and operations of such circuitry, and techniques implemented thereby, are simulated, imitated, replicated, analyzed and/or predicted via a computer system. Simulations and testing of the devices and/or circuitry described herein, and/or techniques implemented thereby, and, as such, are intended to fall within the scope of the present embodiments. The computer-readable media and data corresponding to such simulations and/or testing tools are also intended to fall within the scope of the present embodiments. Furthermore, while PAM signaling is emphasized, the same methods may be applicable to other types of signaling like orthogonal frequency division multiplexing (OFDM, wavelength division multiplexing (WDM) in the case of optical channels, and other multiplexing in which high-speed ADCs are desired.

What is claimed is:

1. An apparatus comprising:
a loop-unrolled (LU) successive approximation register (SAR) analog to digital converter (ADC), the LU-SAR ADC comprising a plurality of comparators connected in series, the plurality of comparators configured to receive a sequence of analog values of a PAM data signal and to convert each analog value of the PAM data signal into a digital output code comprising a plurality of bits, each bit of the plurality of bits of the digital output code corresponding to a decision of a respective comparator; and
an offset calibration circuit configured to accumulate respective statistical measurements of decisions of at least one comparator based on the digital output codes and to update an offset compensation of a given comparator responsive to the respective statistical measurement of decisions of the given comparator exceeding a threshold.

2. The apparatus of claim 1, wherein the offset calibration circuit is configured to accumulate the respective statistical measurement of decisions in corresponding registers, and responsive to the statistical measurement of decisions of a given comparator exceeding the threshold, providing a comparator offset correction value to the given comparator.

3. The apparatus of claim 2, wherein the offset correction value is a fixed step value.

4. The apparatus of claim 2, wherein the offset correction value is dependent on a bit position of the plurality of bits of the digital output code associated with the given comparator.

5. The apparatus of claim 2, wherein the offset correction value is dependent on the statistical measurement of decisions of at least one other comparator of the plurality of comparators.

6. The apparatus of claim 1, further comprising a barrel shifter configured to periodically alternate the plurality of comparators through bit positions of the plurality of bits of the digital output code.

7. The apparatus of claim 6, wherein each comparator is configured to receive a respective phase of a conversion clock signal, and wherein the barrel shifter is configured to select the respective phase of the conversion clock signal for each comparator.

8. The apparatus of claim 6, wherein the LU SAR-ADC further comprises a capacitor network configured to store the analog value on a differential pair of nodes for each conversion, and wherein each capacitor in the capacitor network is configured to receive a decision from a respective comparator manipulate the analog voltage based on the decision.

9. The apparatus of claim 8, wherein the barrel shifter is configured to select, for each capacitor in the array, the decision received by the capacitor.

10. The apparatus of claim 1, wherein the offset calibration circuit is configured to update the offset compensation of the comparator associated with a MSB of the digital output code first.

11. A method comprising:
receiving, at a loop-unrolled (LU) successive approximation register (SAR) analog to digital converter (ADC), a sequence of analog values of a PAM data signal;
converting each analog value of the PAM data signal into a digital output code comprising a plurality of bits, each bit of the plurality of bits of the digital output code corresponding to a decision of a respective comparator of a plurality of comparators of the LU SAR ADC;
accumulating respective statistical measurements of decisions of at least one given comparator based on the digital output codes; and
updating an offset compensation of a given comparator responsive to the respective statistical measurement of decisions of the given comparator exceeding a threshold.

12. The method of claim 11, accumulating the respective statistical measurements of decisions comprises modifying register values of corresponding registers, and responsive to the statistical measurement of decisions of a given comparator exceeding the threshold, updating the offset compensation of the given comparator comprises providing a comparator offset correction value to the given comparator.

13. The method of claim 12, wherein the offset correction value is a fixed step value.

14. The method of claim 12, wherein the offset correction value is dependent on a bit position of the plurality of bits of the digital output code associated with the given comparator.

15. The method of claim 12, wherein the offset correction value is dependent on the statistical measurement of decisions of at least one other comparator of the plurality of comparators.

16. The method of claim 11, further comprising periodically alternating, using a barrel shifter, the plurality of comparators through bit positions of the plurality of bits of the digital output code.

17. The method of claim 16, further comprising receiving, at each comparator, a respective phase of a conversion clock signal.

18. The method of claim 17, further comprising selecting, for each comparator, the respective phase of the conversion clock signal for each comparator using the barrel shifter.

19. The method of claim 16, wherein converting each analog value of the PAM data signal comprises providing decisions from each comparator to corresponding capacitors in a capacitor network.

20. The method of claim 19, wherein further comprising selecting, for each capacitor in the array, the decision received by the capacitor.
